(19) United States
(12) Patent Application Publication
(10) Pub. No.: US 2006/0040067 A1
(43) Pub. Date: Feb. 23, 2006

(54) Discharge-enhanced atmospheric pressure chemical vapor deposition

(76) Inventors: Thomas Culp, La Crosse, WI (US); Roman Korotkov, King of Prussia, PA (US); Ravi Gupta, Norristown, PA (US)

Correspondence Address: ARKEMA INC.;PATENT DEPARTMENT - 26TH FLOOR, 2000 MARKET STREET, PHILADELPHIA, PA, 19103-3222, US

(21) Appl. No.: 10/924,223

(22) Filed: Aug. 23, 2004

(51) Int. Cl. H05H 1/24; C23C 16/00

(52) U.S. Cl. 427/569; 118/723 E

(57) ABSTRACT

A discharge-enhanced CVD apparatus and method utilizes a nozzle containing electrodes to generate a high voltage electrical discharge at or near atmospheric pressure in the absence of a stabilizing or arc-suppressing noble gas. Reactants are passed directly through or/and under the discharge before being directed to the surface of a substrate to be coated.

### BACKGROUND OF THE INVENTION

1. Field of the Invention

This invention relates to a method and apparatus for performing chemical vapor deposition (CVD) at atmospheric pressure, and preferably at relatively low substrate temperatures, by passing the reactants through an electrical discharge such as a dielectric barrier, glow or corona arc discharges in order to raise the reactivity of the reactants and thereby increase the rate of surface reactions that result in coating or surface modification of the substrate.

The invention also relates to a CVD coating nozzle that incorporates electrodes to produce an electrical discharge.

2. Description of Related Art

Chemical vapor deposition is a well-known process by which gas phase reactants are directed to a heated substrate, where surface reactions can cause a modification to the surface of the substrate or a thin layer of material to be deposited on the substrate. This method has been used to modify various surfaces and deposit a wide range of inorganic materials including ceramics, dielectrics, semiconductors, superconductors, and metals. In general, however, appreciable growth and/or reaction rates using conventional CVD are attainable only at relatively high substrate temperatures (500-1200° C.). These high temperatures prevent the use of CVD for surface modification or deposition on thermally sensitive substrates such as polymers.

To deposit materials at lower substrate temperatures, one possibility is to use plasma enhanced chemical vapor deposition (PECVD), in which the reactants and substrate are held within a stabilized plasma in order to increase the reaction rate. However, in order to provide a stable plasma, conventional PECVD is typically performed in vacuum systems at pressures ranging from a few hundred μTorr to a few Torr. The use of vacuum chambers and pumping systems greatly increases the cost and difficulty in scale-up for large volume manufacturing and continuous processes.

In order to eliminate the need for vacuum systems while still enabling CVD to be performed at relatively low substrate temperatures, atmospheric pressure plasma techniques such as discharge enhanced chemical vapor deposition (DECVD) may be used. These techniques rely on passage of reactants through an electrical discharge at or near atmospheric pressure. Current discharge-enhanced CVD techniques known in the literature all utilize one or more of the following features, each of which impart certain limitations:
1. the reactants are passed through an electrical plasma discharge that has been stabilized by the presence of noble gases such as He and Ar;
2. the substrate is located between the electrodes creating the discharge or plasma;
3. the reactant flow and/or electrical discharge are created using either a single cylindrical nozzle or an array of cylindrical nozzles.

Noble gases such as He, Ne, and Ar are often used to prevent microarcing and stabilize the plasma discharge. However, the principal disadvantage oftechniques which use noble gases is that the higher cost of noble gases increases the overall process costs. The use of noble gases is a particular disadvantage in atmospheric pressure techniques compared to low pressure PECVD because much higher volumes of gases are required.

Examples of atmospheric pressure discharge techniques utilizing electrode-to-electrode discharge in the presence of noble gases are disclosed in U.S. Pat. Nos. 6,194,036 (use of He to prevent arcs); U.S. Pat, No. 6,262,523 (arcless discharge); U.S. Pat. No. 5,185,132 (rare gas); U.S. Pat. No. 5,198,724 (corona or glow discharge with 70% He, primarily for etching); U.S. Pat. No. 5,549,780 (rare gas, etching); U.S. Pat. No. 6,013,153 (rubber treatment with rare gas); and U.S. Pat. No. 5,185,153 (rare gas, etching or deposition); International Patent Publications WO 99/42636 (Argon) and WO 99/20809; Inomata et al., Applied Physics Letters, vol. 64, p. 46 (1994); Ha et al., Applied Physics Letters, vol. 68, p.2965 (1996); Babayan et al., Plasma Sources Sci. Technol., vol. 7, page 286 (1998); Schütze et al., IEEE Transactions On Plasma Science, vol. 26, p. 1685 (1998); and Japanese Patent Publication Nos. JP 6330326 and JP 11003798.

Several prior DECVD techniques permit or utilize arcing and do not require noble gases, but only with the substrate located between the electrodes. However, the placement of the substrate between the electrodes suffers from several disadvantages including increased difficulty of substrate manipulation during manufacturing, potential interference of the discharge by the substrate, and potential increased damage to the substrate surface created by the discharge. Examples of DECVD techniques in which the substrate is placed between the electrodes include Thyen et al., “Deposition Of Various Inorganic Films Using Dielectric Barrier Discharge,” Surface Coating Technology, vol. 97, p. 426 (1997) or Salge, “Deposition Of Polymeric Films On Glass Using Dielectric Barrier Discharge,” Surface Coating Technology, vol. 80, page 1 (1996), and U.S. Pat. No. 5,972,176 (corona treatment of polymer surfaces). Other references that disclose direct electrode-to-surface electrical discharge include U.S. Pat. Nos. 5,384,167; 5,126,164; 5,529,631; and 5,733,610; and European Patent Publication Nos. EP 0346055 and EP 0603784.

Also of particular interest is International Patent Publication No. WO 00/70117 which, on page 24, lines 11-20, draws a distinction between plasma discharge processes carried out at pressures below 100 Torr, which do not benefit from the presence of noble gases, and processes carried out at pressures above 100 Torr (atmospheric pressure being defined as 760 Torr), in which noble gases provide a stabilizing effect. Like the other references cited above, WO 00/70117 does not address the high cost of vacuum processing or noble gases, either of which makes conventional discharge deposition methods of the type disclosed in WO 00/70117 impractical for many coating applications.

Some atmospheric pressure discharge techniques do not require the substrate be placed between the electrodes, and pass a reactant gas between electrodes to form an atmospheric pressure plasma and deposit a coating on a substrate downstream from the electrodes. Examples include U.S. Pat. Nos. 5,198,724; 5,185,132; and International Patent Publication No. WO 99/20809. However, each of these teach the use of noble gases such as He, Ne, or Ar to stabilize the plasma without addressing the increased processing costs. Furthermore, U.S. Pat . No. 5,185,132 and WO 99/20809 use cylindrical nozzle electrode configurations which create a cylindrical beam geometry for the plasma reactant stream. This configuration is disadvantageous in that the coating area is highly limited with a single device. Scale-up for coating large areas using a single or multiple devices is difficult, both in terms of manufacture and maintaining a uniform discharge across the surface. Similarly, U.S. Patent Application Publication Nos. 2002/0171367 A1 and 2003/0129107 A1 do not specifically require noble gases, but also use cylindrical electrode configuration either as a single device or an array, making scale-up to coat or modify large surface areas difficult.

In general, prior art low-substrate-temperature plasma or discharge deposition methods have required either that processing be carried out in a vacuum, the substrate be placed directly between the electrodes, noble gases be used as a stabilizer, and/or cylindrical electrode configuration be used. The present invention improves upon conventional PECVD or DECVD techniques by creating an electrical discharge with linear geometry at or near atmospheric pressure using electrodes above the substrate without stabilization by noble gases. This is different than the cylindrical nozzles of the art. This improved technique can easily and economically be scaled-up to coat or modify large surface areas in comparison to previous techniques.

### SUMMARY OF THE INVENTION

It is accordingly an objective of the invention to provide a low temperature, atmospheric pressure CVD method and apparatus that may be implemented at relatively low cost, without the use of noble gases as stabilizers.

It is a second objective of the invention to provide a low temperature, atmospheric pressure CVD method and apparatus that is easily scalable for large area production and continuous processes.

It is a third objective of the invention to provide a low temperature, atmospheric pressure CVD method and apparatus that enables coating and surface modification of a wide variety of substrate sizes, shapes, and materials.

It is a fourth objective of the invention to provide a method and apparatus that provides for faster deposition or surface modification at lower temperatures.

These objectives of the invention are achieved, in accordance with the principles of a preferred embodiment of the invention with a method for surface treating a substrate comprising the steps of:
a) positioning an electrode assembly above a substrate;
b) generating a high voltage discharge;
c) passing reactants and carrier gas through or/and under the electrical discharge to the substrate, resulting in modification of the substrate surface.

In a preferred embodiment the use of noble gases is not required.

In a preferred embodiment, a new coating nozzle is used which incorporates electrodes to produce a dielectric barrier discharge.

### DETAILED DESCRIPTION OF THE INVENTION

A dielectric barrier discharge can be created by applying an alternating high voltage to two electrodes typically separated by 0.5-10 mm. The voltage can either be supplied continuously or as a series of pulses. At least one of the electrodes is covered with an insulating material such as glass, alumina, or quartz to act as a dielectric barrier. Breakdown processes lead to short duration, localized discharges which contain ionized gas species and energetic electrons with energies of approximately 1-10 eV (roughly 100-1000 kJ/mol). In this nonequilibrium state, the effective electron temperature can be well over 10,000° C. while the bulk gas temperature remains relatively low. Vaporized reactants and carrier gas, passing through the discharges to the substrate form activated species or/and partially decompose. The resulting species react with the substrate surface and deposit a coating.

For metal-containing coatings, the reactants may include metal precursors for the specific material (e.g., C₄H₉SnCl₃ for SnO₂) and anion precursors which are often part of the carrier gas (e.g., O₂ for oxides, CH₄ or C₂H₂ for carbides, and NH₃ or N₂ for nitrides). Because of the electrical activation, less expensive reactants such as metal halides could be used instead of the more expensive acetylacetonate based precursors often used in traditional CVD.

Potential applications for a lower temperature open CVD system are numerous. First, the system of the invention will extend the operating range for atmospheric pressure chemical vapor deposition of oxide materials such as SnO₂, SiO₂, TiO₂, Cr₂O₃, Al₂O₃, and WO₃ to lower temperatures than normally used (commonly 500-1000° C.).

Second, at even lower temperatures less than 200° C., and preferably 0-200° C., surface treatments and coatings on plastic substrates are possible. Conductive coatings (e.g. SnO₂:F, Sn:In₂O₃, or TiN) on plastics can be used for low-emissivity plastic glazing, transparent electrodes in plastic touch-screen LCDs, antistatic coatings, primer coatings for electrostatic painting, or low-level electromagnetic shielding. Hard coatings such as SiO₂, Al₂O₃, or TiO₂ can be used to give additional scratch resistance to plastics such as, but not limited to polycarbonate, ABS terpolymer, ASA copolymer, polyester, PETG, MBS copolymer, HIPS, acrylonitrile/acrylate copolymer, polystyrene, SAN, MMA/S, an acrylonitrile/methyl methacrylate copolymer, impact modified polyolefins, PVC, impact modified PVC, imidized acrylic polymer, fluoropolymers, polyvinylidenedifluoride (PVDF), PVDF-acrylic polymer blends, and acrylic polymers such as polymethylmethacrylate or impact modified acrylic polymer. UV absorbing or reflection coatings could be used for UV protection of plastics. A plastic may be surface treated to improve the substrate properties, such as for example fluorination.

Third, hard boride, carbide, nitride, and oxide materials traditionally deposited at very high temperatures (900-1300° C.) can be deposited at more moderate temperatures (400-700° C.). Applications for these materials include wear-resistant, corrosion-resistant, or oxidation-resistant coatings on tool inserts, turbine blades, engine components, and other metal or ceramic parts. If these hard coatings can be produced in a lower temperature deposition system, capital and operating costs will be reduced, and a wider range of substrate materials can be used. One potential application for wear or corrosion resistant materials is online coating of sheet metals or piping.

Fourth, in addition to metal-containing coatings, the method of the invention can possibly be used to deposit other materials such as organic polymeric coatings, fluorocarbon coatings, and carbon coatings (graphite, fullerenes, or diamond-like-carbon). Likewise, the surface can be modified with specific chemical functional groups. Depending upon the specific material, these coatings can be lubricious, protective, conductive, chemically active (catalytic or functionalizable), and/or chemically less active. Again, this method can possibly allow these materials to be deposited at lower temperatures in an open system at atmospheric pressure.

In conventional low pressure plasma enhanced CVD, the deposition kinetics are also enhanced by electrical means, but the key advantage of the present invention over low pressure plasma enhanced CVD is that the electrical discharge nozzle design can easily be expanded to coat arbitrarily wide substrates such as but not limited to sheets. The method does not require vacuum chambers or vacuum pumps, which are expensive and/or difficult to scale up for coating large substrates. The exhaust system only requires standard blowers, so the entire process occurs essentially at atmospheric pressure. Another advantage is that the equipment is mounted above the substrate, and no part is in contact with the substrate. The substrate does not need to be fed into a coating chamber or electrode assembly which surrounds the substrate on top and bottom. This is an advantage where the coating equipment must be installed without disturbing the existing process line, or where it is impractical to manipulate or surround the substrate (e.g. continuous glass or polymer sheet processes).

### BRIEF DESCRIPTION OF THE DRAWINGS

FIG. 1 is a schematic, cross-sectional view of a linear slit-type nozzle apparatus constructed in accordance with the principles of a first preferred embodiment of the invention.

FIG. 2 is a schematic, cross-sectional view of a linear slit-type nozzle apparatus constructed in accordance with the principles of a second preferred embodiment of the invention.

FIG. 3 is a schematic view of a linear nozzle apparatus utilizing multiple electrodes and constructed in accordance with the principles of a third preferred embodiment of the invention.

FIG. 4(a and b) is a schematic view of the DECVD system used in Example 1.

FIG. 5 is a schematic showing the DECVD reactor nozzle mounted on a stage to control the gap between the electrode and substrate.

FIG. 6 diagrams several flow rate geometries, as described in Example 1.

FIG. 7 is the XPS spectra for an SnO₂ sample from Example 1.

FIG. 8 is the grazing angle x-ray diffraction patterns of an SnO₂ sample from Example 1, following annealing at 300° C.

### DETAILED DESCRIPTION OF THE PREFERRED EMBODIMENTS

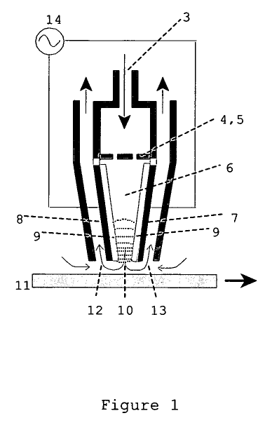

FIG. 1 shows a discharge enhanced CVD nozzle 1 constructed in accordance with the principles of a first preferred embodiment of the invention. The nozzle 1 of FIG. 1 is a slot nozzle having a housing 2 that includes an inlet slot 3 through which vaporized reactants and carrier gases are introduced, a distribution plate 4 including slots or apertures 5 for passing the reactants to a discharge chamber 6 between two metal plate electrodes 7,8 covered by a dielectric material 9 for generating a high voltage discharge that energizes the reactants before discharge through an elongated slot 10. The reactants, including ionized and dissociated species created by electrical discharge between the electrodes, impinge upon the substrate 11 and react with the surface and/or deposit a coating at atmospheric pressure.

According to the principles of the invention, the electrical discharge is carried out in the absence of a stabilizing noble gas such as He or Ar, although minor amounts of He and Ar may be included so long as the noble gas does not preclude arcing. The carrier gas may be chosen to provide an inert or reducing environment using gases such as N₂, NH₃, or H₂, or an oxidizing environment using gases such as air, O₂, or NO₂. To deposit metals or metal-containing compounds, an appropriate volatile organometallic or inorganic precursor containing the desired metal element is selected.

In the embodiment of FIG. 1, reaction products and unreacted gases are removed through two outer exhaust slots 12,13. An exhaust blower (not shown) can be set to draw a higher volumetric flow than the reactant vapors exiting the center outlet slot 10. This overexhaust condition will draw additional gas from outside of the coating equipment, thus minimizing the escape of reactant vapors from the coating equipment to the exterior environment.

The electrodes preferably form or are incorporated into the nozzle to produce an electrical discharge such as a dielectric barrier discharge. A dielectric barrier discharge can be created by applying an alternating high voltage from power source 14 to electrodes 7, 8, which are typically separated by 0.5-10 mm. The voltage can either be supplied continuously or as a series of pulses. To accomplish the dielectric barrier discharge, insulating material 9 must be positioned adjacent to or on at least one of the electrodes, and may be made of any material that acts as a dielectric barrier, including but not limited to glass, alumina, or quartz. Breakdown processes lead to short duration, localized discharges which contain ionized gas species and energetic electrons. In the resulting nonequilibrium state, the effective electron temperature can be several thousand degrees while the bulk gas temperature remains relatively low.

The nozzle of FIG. 1 is illustrated as elongated in a direction extending into the page. It will be appreciated that the nozzle may be elongated as needed to coat substrates of arbitrary width. For a finite sized substrate, the coating nozzle can be scanned over the length of the substrate or, for continuous, arbitrarily long substrates, the substrate can be advanced underneath a stationary nozzle, as illustrated in FIG. 1.

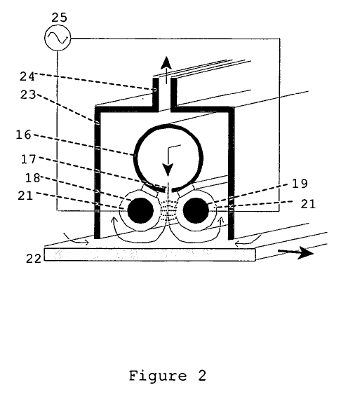

The nozzle 15 of FIG. 2 is a dual-rod nozzle, in which gases enter a top pipe 16, exit through slot 17, and flow down between two metal rod electrodes 18,19 covered by dielectric tubes 21 and arranged to generate a dielectric barrier or other high voltage discharge when connected to an alternating current power source or pulse generator/circuitry 25, in the manner described above in connection with the embodiment of FIG. 1, unmediated by a noble or rare gas. After the vapors impinge on the substrate 22 and react with the surface and/or deposit the coating, they are removed through an outer exhaust cover 23 having an outlet slot 24.

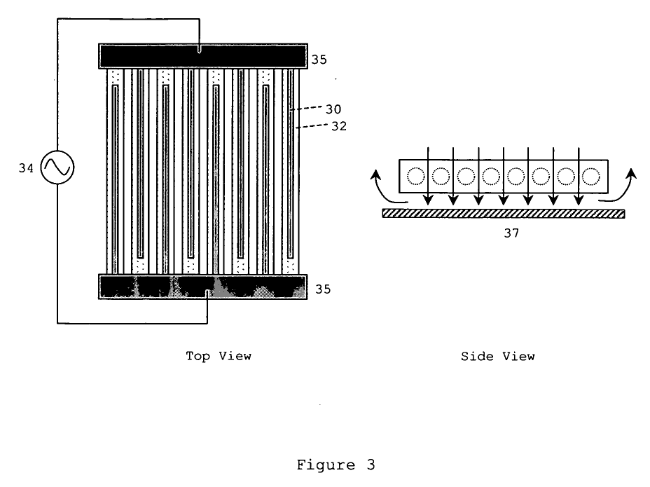

FIG. 3 shows another preferred embodiment of the invention, in which multiple parallel, arbitrarily long, metal rods 30 covered with alumina ceramic tubes 32 form alternating electrodes connected to a high voltage power supply 34 from bus bars 35 at opposite ends. The rods may be touching or spaced apart by a small distance. This arrangement creates an atmospheric pressure plasma discharge between and around each pair of rods, but with a larger total discharge area than a single pair of electrodes. Reactant and carrier gases may be passed down through the discharge between the rods to the substrate 37, where they react with the surface and are evacuated to the sides. Alternately, the rod assembly may be placed parallel and close to the substrate surface such that the discharge extends across the gap between the assembly and substrate, and the vapors enter the gap from one side of the assembly flowing parallel to the substrate surface, react with the surface, and are evacuated from the other side of the assembly.

It will be appreciated that the nozzle configurations illustrated in FIGS. 1, 2, and 3 are not intended to be limiting, and that the structure of the nozzles may be varied in numerous ways without departing from the scope of the invention, so long as the nozzle includes at least two electrodes capable of generating an electrical discharge of arbitrary length. For example, only one of the electrodes needs to be covered with a dielectric material, rather than both electrodes. Also, the electrodes can be parallel plates, tilted plates, rods, or curved structures arranged to optimize the laminar flow pattern. Alternatively, multiple electrode slots may be employed, with a variety of different exhaust configurations, and the nozzle body can be heated or cooled to optimize temperature control. Although not shown, the exhaust walls and nozzle body should be insulated and spaced from the electrodes, or possibly held at a certain potential such that the discharge only occurs between the electrodes.

Of course, the exact nozzle design and flow conditions may be optimized to minimize homogenous nucleation of the excited reactants above the substrate, which can lead to particle formation, and to maximize surface nucleation of the reactants on the substrate to promote coating deposition. In addition, in order to have a uniform distribution of discharges and reactant excitation along the length of the coating nozzle, the electrodes must be closely aligned to have a uniform gap across the entire nozzle length. To overcome slight misalignments which could lead to preferential discharging at one end of the electrodes, the length of the electrodes could be divided into shorter electrode sections, each connected to a separate electric circuit, since obtaining a uniform alignment is easier over a shorter distance, and misalignment in one section will not affect other sections.

To better control the distribution of discharges along the electrodes, the electrode surface or edge may include projections instead of just being smooth. For example, the electrode edge can be serrated with a tooth-like pattern. In this case, the microdischarges preferentially form at the points where the gap is narrowest, resulting in consistent reactant excitation locations rather than randomly distributed discharges along the electrode. The shape and spacing of the projections can be optimized to provide the most uniform and consistent surface reaction or coating. If sharp projections are used and the dielectric material is omitted, a corona discharge may be produced at lower currents and voltages compared to dielectric barrier discharges.

An advantage of the DECVD technique used in the preferred embodiments of the invention is that the nozzle design can easily be expanded to coat arbitrarily wide substrates, and may be used in continuous processes to coat arbitrarily long substrates by advancing the substrate underneath the nozzle. Because neither vacuum systems nor expensive noble gases are required, large surface areas may be treated in an economic manner.

The method of the invention simply involves positioning the electrode assembly above a substrate (or positioning the substrate under the electrodes), followed by generation of a dielectric barrier discharge, corona discharge, or similar high voltage discharge, in the absence of a stabilizing or arc-suppressing noble gas, and passing the reactants and carrier gas through the discharge to the substrate, in order to form a coating or surface modification due to reactions with the substrate. Although the above descriptions have only described treating one surface of the substrate, the method may be extended to include discharge nozzles on both sides of the substrate in order to simultaneously treat both surfaces. The method may be carried out at low substrate temperatures and at atmospheric pressure, although it is within the scope of the invention to use lower pressures and higher temperatures, depending on the material of the substrate and reactants and so long as an appropriate discharge between the electrodes may be maintained.

In one embodiment, the coating applied at low temperatures forms an amorphous coating. The coating may be annealed to produce a crystalline structure by heating the substrate to an elevated temperature and for a long enough duration.

In another embodiment, the surface treatment is applied to a heated substrate, leading to an annealed, crystalline coating. One method would be to apply the coating very soon after the formation of the substrate, while it is still at an elevated temperature.

Having thus described a preferred embodiment of the invention in sufficient detail to enable those skilled in the art to make and use the invention, it will nevertheless be appreciated that numerous variations and modifications of the illustrated embodiment may be made without departing from the spirit of the invention, and it is intended that the invention not be limited by the above description, the listed examples, or accompanying drawings, but that it be defined solely in accordance with the appended claims.

### EXAMPLE 1

### SnO₂ Deposition at Room Temperature (25° C.) by DECVD

DECVD System Description

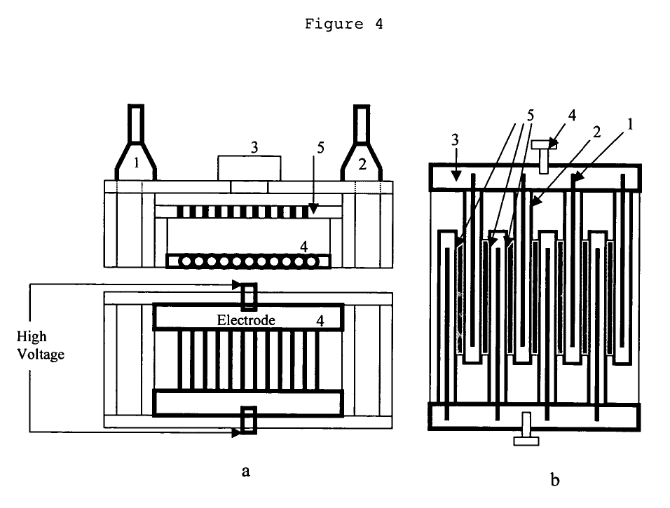

The DECVD reactor used during SnO₂ deposition is depicted in FIG. 4a. The reactor body was made out of nonconductive machinable alumina silicate ceramic with a dielectric strength of 100 V/mil (0.5 inch thick walls). The reactor shown in FIG. 4 was equipped with two side gas entrance slots, such as two side slots 1 and 2, and a central slot 3. Slots 1 and 2 were rectangular 0.5×7 inches. The central slot was circular 0.5 inch in diameter. To allow for adequate homogeneous distribution of gas coming from slot #3 a showerhead, #5 was introduced in the reaction stream, as shown in FIG. 4. The High voltage (HV) electrode, #4, 4 inches wide and 7 inch long was tightly fitted between ceramic walls of the ceramic reactor parallel to the substrate.

The electrode comprised of ⅛ inch in diameter 6-inch long brass rods encapsulated in Al₂O₃ ceramic roads as shown in FIG. 4b. When the brass electrode, #1, was inserted into Al₂O₃ rods, #2, one of the open Al₂O₃ ends was filled with castable alumina ceramic to fully insulate the electrode assembly. The remaining end of the alumina encapsulated brass electrode was inserted into rectangular Al-metal electrode contact plate, #3, at equal distances as shown in FIG. 4b. The high voltage was applied to the electrode with two contact screws, #4. After the HV electrode was fully assembled, to provide structural integrity, the space between electrodes was filled with high strength, high resistivity (10¹⁰ Ohm cm) castable alumina ceramic. The gas entrance slots, #5 were left unfilled. The separation distances between electrodes varied from 0.5 to 2 mm.

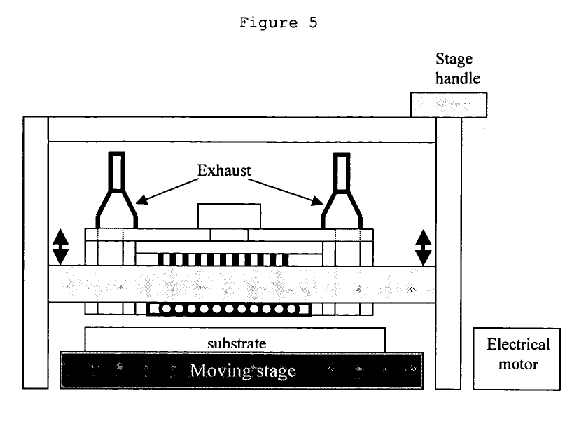

The DECVD reactor nozzle was mounted on a stage, see FIG. 5. To control the gap between the DECVD electrode and the substrate, the distance between the nozzle and the substrate was varied with a micrometer in vertical direction. In a continuous operation mode the substrate was placed on top of a moving 1 -inch thick ceramic plate (100 V/mil). The horizontal movement of the stage was realized with a speed-controlled motor, see FIG. 5.

SnO₂ Deposition—Reactants Flow Rate Geometries

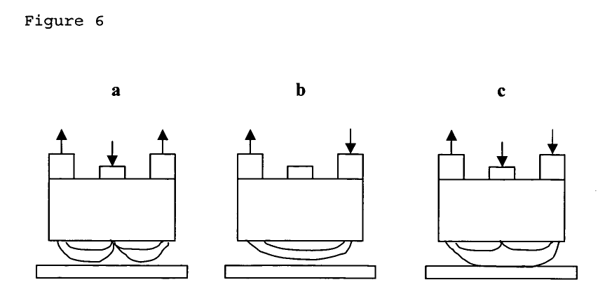

Several reactants flow rate geometries were studied as shown in FIG. 6a-c. In the first geometry, reaction mixture is directed trough the central slot #3, FIG. 4a. The unreacted chemistry-carrier gas mixture is picked up by two exhaust slots, #1 and 2, FIG. 4a. The schematic flow geometries are presented in FIG. 6a. In the second geometry, the central slot was blocked, and the chemistry was introduced through the side slot. The unreacted chemistry was picked up by the other side slot as shown in FIG. 6b. For the last flow geometry, all slots were used. For example, the carrier gas, N₂, was introduced through the side slot, #2 in FIG. 4a. The oxidizer, such as O₂ or air was introduced through the central slot, #3 in FIG. 4a. The non-reacted reactants and the carrier gases were picked up by the other exhaust slot, see FIG. 6c.

SnO₂ Deposition Conditions

Two different Sn metalorganic sources were used during SnO₂ deposition using DECVD, such as monobutyl-tin-trichloride (MBTC) and tetrabutyl-tin (TBT). Tin metalorganics were injected inside a vaporizer kept at 100-160° C. at predetermined rates using Harvard Apparatus syringe pumps. Pre-heated (100-160° C.) nitrogen (99.998), dry air or pure oxygen (99.995) were used to transfer tin precursors toward substrates. There was no heating of the substrate, except that provided by the impinging flow of the carrier gases. Sodalime silicate glass, 2.5 mm-thick, was utilized as the substrate during the depositions. Glass substrates were cleaned with an NH₄OH solution and blown dry with N₂.

XPS of Selected SnO₂ Films Deposited by DECVD at Room Temperature

A series of SnO₂ films were deposited by DECVD on glass substrate at 25 ° C. using setup presented in FIG. 5. Several SnO₂ coating were analyzed by XPS to prove that as obtained coating were tin oxide. The deposition conditions for these films and XPS mass concentrations for the observed Sn, O, Cl, C and N species for these films are shown in Tables 1-2.

Surface elemental analysis was done with the Kratos HS-AXIS spectrometer. Survey Spectra: were obtained in the following conditions: the monochromatic aluminum anode was used at 210 W for the analysis (15 mA, 14 kV). The hybrid lens mode was selected, and the final aperture was 600×300 μm. Three sweeps (0-1340 eV) were acquired at 1 eV step, with a dwell of 500 ms, and a pass energy of 160 eV. Region spectra: were acquired for Sn 3d, O 1s, C 1s, Cl 2p, and, N 1s and the valence band regions in the following conditions: Five sweeps were collected at 0.1 eV step, 2,000 ms dwell, and 40 eV pass energy. All the region spectra were acquired at 210 W with the monochromatic aluminum anode (20 mA, 14 kV). A 70% Gaussian-30% Lorentzian functions is used to model the peaks for all decomposition work.

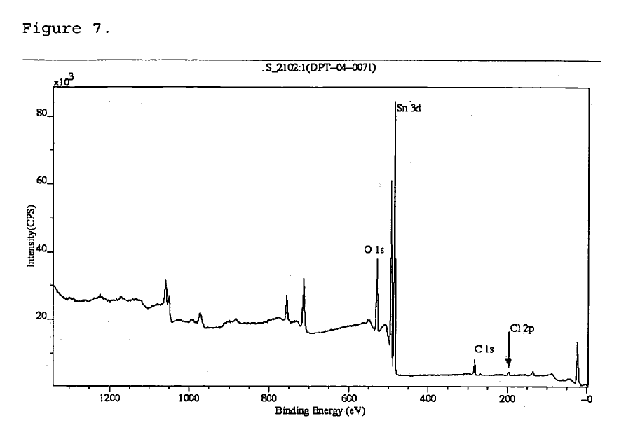

Stannic tin oxide was identified both with the Sn 3d5/2 peak, with the structure of the valence band and the energy shift between the lower energy edge of the valence band and Sn 4d5/2 peak. A selected SnO₂ spectrum for one of the samples deposited by DECVD10 is shown in FIG. 7. Chlorine was detected to significant levels for the samples deposited with MBTC as compared to the film deposited at a similar conditions with TBT, see Table 1. The Si-signal was not detected in these films due the fact that the films were covering all substrate surface and were thick.

1.2 X-ray Spectroscopy of Selected SnO₂ Deposited by DECVD

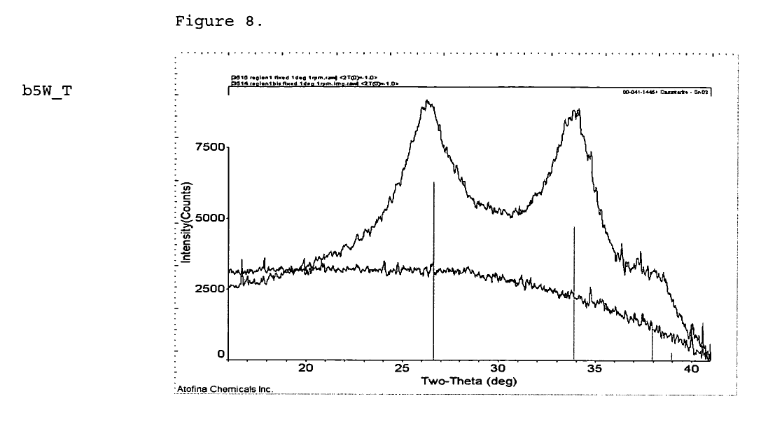

As-grown SnO₂ films deposited on glass substrate were amorphous as shown in FIG. 8 lower curve, where grazing angle x-ray diffractormeter was used (Rigaku Ultima II X-ray diffractometer with fixed divergence slits, the mirror optic, and the Mercury CCD detector, in the following conditions: Tube current=40 mA, Tube voltage=40 kV, Radiation Cu K-alpha, Theta inf=29°, Theta sup=31°, divergence slit=1 mm, exposure time=600 s, divergence H slit=0.5 mm, divergence Soller slit=2.5°, parallel beam geometry, theta source fixed angle=1°).

When as-grown by DECVD SnO₂ films were annealed in an open air environment at 300° C., the x-ray pattern changes drastically, see upper curve in FIG. 8. A crystalline SnO₂ cassiterite phase was identified in the coating deposited with TBT and annealed at 300° C. The regular peak position for the rutile (cassiterite) SnO₂ is shown with the solid vertical lines in FIG. 8. These results were an additional proof that as deposited by DECVD thin films were SnO₂ with amorphous structure, that converted to crystalline SnO₂ at elevated temperatures.

DECVD Deposition Growth Rates

SnO₂ film thicknesses obtained by DECVD at room temperature at atmospheric pressure were measured by profilometry. Film thicknesses varied from 200 nm to 5 μm. The growth rate varied in the range 54-757 nm/min.

TABLE 1
Mass percent of Sn, O, C, Cl and N in
SnO₂ deposited by DECVD as measured by XPS

| # | Sn % | O % | C % | Cl % | N % |
|---|---|---|---|---|---|
| DECVD10¹ | 76.3 | 15.1 | 7.2 | 1.3 | 0.1 |
| DECVD17² | 64.7 | 13.6 | 10.2 | 9.2 | 2.4 |
| 12294-081-01³ | 70.8 | 16.8 | 6.7 | 5.2 | 0.5 |
| 12294-091-06⁴ | 64.6 | 12.9 | 21.4 | — | 1.0 |

TABLE 2
Deposition conditions for the selected SnO₂ films on glass by DECVD

| | Gas | FR #2 | | | | | | | H₂O | Gas | FR #3 |
|---|---|---|---|---|---|---|---|---|---|---|---|
| # | # 2 | L/min | Metorg | ml/h | ° C. | W | kHz | min | ml/h | #3 | L/min |
| DECVD10¹ | — | — | MBTC | 2 | 130 | 400 | 14 | 10 | — | air | 35 |
| DECVD17² | N₂ | 35 | MBTC | 3 | 130 | 250 | 6.8 | 5 | — | — | — |
| 12294-081-01³ | — | — | MBTC | 9.9 | 160 | 220 | 5 | 6 | 3.3 | air | 12 |
| 12294-091-06⁴ | N₂ | 15 | TBT | 3 | 150 | 230 | — | 7 | 6 | air | 3 |

¹Flow geometry was of that presented in FIG. 6a.
²Flow geometry was of that presented in FIG. 6b.
³Flow geometry was of that presented in FIG. 6a.
⁴Flow geometry was of that presented in FIG. 6c with H₂O fed through # 3.

We claim:

1. A method for surface treating or coating a substrate comprising the steps of:
a) positioning an electrode assembly above a substrate;
b) generating a high voltage discharge;
c) passing reactants and carrier gas through and/or under the electrical discharge to the substrate, resulting in modification of the substrate surface.

2. The method of claim 1, wherein the process is free of noble gas.

3. The method of claim 1, wherein the high voltage discharge has a linear geometry of variable length.

4. The method of claim 1, wherein the modification of the substrate surface comprises a discharge enhanced chemical vapor deposition (DECVD) resulting in the application of a coating to the substrate.

5. The method of claim 1, wherein the process occurs at or near atmospheric pressure.

6. The method of claim 1, wherein the substrate comprises glass, borosilicate, or a plastic.

7. The method of claim 1, wherein the temperature of the substrate surface is less than 700° C.

8. The method of claim 7, wherein the surface temperature of the surface is less than 200° C.

9. The method of claim 7, wherein the coating is a hard coating selected from the group consisting of boride, carbide, nitride, oxide, and mixtures thereof, and the surface is at from 400 to 700° C.

10. The method of claim 1, wherein the carrier gas is selected from the group consisting of N₂, NH₃, H₂, air, O₂, NO₂, N₂O and mixtures thereof.

11. The method of claim 1, wherein the substrate is at an elevated temperature,
resulting in an annealed, crystalline coating.

12. The method of claim 1 further comprising the step of heating the surface
modified substrate, resulting in an annealed, crystalline coating.

13. A nozzle for discharge-enhanced chemical vapor deposition utilizing glow and corona discharges, comprising:
an inlet arranged to receive a carrier gas and vaporized reactants;
at least two electrodes between which the carrier gas and vaporized reactants pass, said electrodes being connected to an electrical power source to cause a discharge to form between said electrodes and thereby energize said reactants;
an outlet arranged to direct said energized reactants to a substrate,
wherein said discharge is a high voltage discharge generated in the absence of a stabilizing or arc-suppressing gas.

14. A nozzle as claimed in claim 13, wherein at least one of said electrodes is covered with a dielectric material, and said discharge is a dielectric barrier discharge.

15. A nozzle as claimed in claim 13, wherein at least two of said electrodes are covered with a dielectric material.

16. A nozzle as claimed in claim 13, wherein said discharge is a corona (glow) discharge.

17. A nozzle as claimed in claim 13, wherein said electrodes are plate electrodes.

18. A nozzle as claimed in claim 13, further comprising exhaust passages adjacent to an outside of said electrodes, said exhaust passages being arranged to exhaust reaction products.

19. A nozzle as claimed in claim 13, wherein said electrodes are cylindrical rods.

20. A nozzle as claimed in claim 13, wherein at least one of said electrodes is covered with a dielectric material and said discharge is a dielectric barrier discharge.

21. A nozzle as claimed in claim 13, wherein said nozzle is stationary and said substrate is moved relative to said nozzle.

22. Apparatus for discharge-enhanced chemical vapor deposition utilizing arc discharges, comprising:
at least two electrodes between which a carrier gas and vaporized reactants pass, said two electrodes being positioned on a same side of a substrate; and
a high voltage power source arranged to cause a discharge to form between said electrodes and thereby energize said reactants;
wherein said discharge is a high voltage discharge generated in the absence of a stabilizing or arc-suppressing gas.

23. Apparatus as claimed in claim 22, wherein at least one of said electrodes is covered with a dielectric material, and said discharge is a dielectric barrier discharge.

24. Apparatus as claimed in claim 22, wherein at least two of said electrodes are covered with a dielectric material.

25. Apparatus as claimed in claim 22, wherein said discharge is a corona discharge.

26. A method of coating or surface treating a substrate, comprising the steps of:
positioning at least two electrodes above a substrate;
generating a high voltage discharge between the electrodes in the absence of a stabilizing or arc-suppressing gas;
passing a carrier gas and reactants between the electrodes in order to energize the reactants and cause them to react with the substrate and form a coating thereon.
